(19) United States
(12) Patent Application Publication
(10) Pub. No.: US 2022/0187341 A1
(43) Pub. Date: Jun. 16, 2022

(54) MICROELECTRONIC TEST INTERFACE SUBSTRATES, DEVICES, AND METHODS OF MANUFACTURE THEREOF LAYER LEVEL TEST AND REPAIR ON BUILDUP REDISTRIBUTION LAYERS

(71) Applicant: Raymond Won Bae, Danville, CA (US)

(72) Inventor: Raymond Won Bae, Danville, CA (US)

(21) Appl. No.: 17/514,225

(22) Filed: Oct. 29, 2021

Related U.S. Application Data
(60) Provisional application No. 63/199,220, filed on Dec. 15, 2020.

(51) Int. Cl. G01R 3/00; G01R 31/28

(52) U.S. Cl. CPC G01R 3/00; G01R 31/2886

(57) ABSTRACT

An embodiment of the present invention provides a method and system of manufacturing a redistribution platform comprising: providing a substrate; patterning a first layer of a routing trace over the base substrate; testing the first layer of the routing traces; repair of any defect traces; re-patterning of defect traces; testing the first layer of routing traces for validation of the 1^{st} layer routing traces; repeating the 2^{nd} layer to each consequent buildup layers as the 1^{st} layer patterning of a routing traces, testing of a routing traces, re-patterning of defect traces and testing of layer routing traces for validation.

### TECHNICAL FIELD

An embodiment of the present invention relates generally to microelectronic buildup redistribution layer system.

### BACKGROUND

The interface substrate and device designs are increasingly become more complex in terms of layer counts and circuit density. In fact, the term microelectronic defines the extreme small formfactor, complexity in design and massive functionality in circuitry of electronic wafer chip and devices. This complexity creates the not only the low yield in production with the increase in the delivery lead-time but decrease in reliability with the increase in the cost. The current method of test interface substrate manufacturing thereof is based on the testing at the end of fabrication and repair is almost impossible. Modern consumer and industrial electronics, cellular phones, mobile devices, and computing systems, are providing increasing levels of volume production to require more and more faster, flexible, and reliable test interface substrate to meet the market demands. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, reliable testing and faster delivery of wafers through new devices has become a concern for manufactures.

Thus, a need still remains for a microelectronic buildup redistribution layer system for testing of wafers and devices. In view of the ever-increasing commercial competitive pressures, along with growing consumer expectations and the diminishing opportunities for meaningful product differentiation in the marketplace, it is increasingly critical that answers be found to these problems. Additionally, the need to provide with manufacturing capabilities of redistribution system layer to layer levels of reliable testing and repairable buildup process to reduce the lead-time, reduce costs by increasing yields, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a microelectronic redistribution buildup layer system, including: a base carrier substrate; conductor traces and a dielectric structure on the substrate, including a plurality of multi-layers.

An embodiment of the present invention provides a method of manufacture thereof validating the functionality by electrical test and repair capabilities of each of redistribution buildup layers to reduce the lead-time and scraps due to defects in test interface substrates. Microelectronic buildup redistribution layer system including: providing a base carrier substrate; forming a plurality of multi-layers on the substrate, conductor traces, conductor vias and a dielectric structure on the substrate.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of a probe card system in an embodiment of the present invention microelectronics test interface redistribution layer system 300 is integrated.

FIG. 2 schematic view of an embodiment of microelectronic test interface substrate system 700 with the base carrier substrate bottom view and microelectronic buildup redistribution layer top view with conductor traces and test pads.

FIG. 3 is a schematic cross-sectional side view of an embodiment of microelectronic test interface substrate system 700 traces along line 10-10 in FIG. 2

FIG. 4 is a schematic cross-sectional side view of an embodiment of microelectronic test interface substrate system with base carrier substrate and 1^{st} microelectronic buildup redistribution layer conductor traces.

FIG. 5 is a schematic top view of an embodiment of microelectronic test interface substrate system with base carrier substrate and 1^{st} microelectronic buildup redistribution layer conductor traces with the example of normal pair, open trace pair, short trace pair and damaged trace pair.

FIG. 6 is a schematic top view of an embodiment of microelectronic test interface substrate system with base carrier substrate and 1^{st} microelectronic redistribution buildup cross lined thru normal pairs, open pairs, short pairs, and damage pairs of conductor traces along line 5-5.

FIG. 7 is a schematic cross-sectional side view of an embodiment of microelectronic test interface substrate system FIG. 6 along line 5-5.

FIG. 8 is a schematic top view of an embodiment with thin conductive seed layer deposition 910.

FIG. 9 a schematic cross-sectional side view of an embodiment of microelectronic test interface substrate system FIG. 8 along line 6-6.

FIG. 10 is a schematic top view of an embodiment with resist or mask 920 layer applied and developed 950.

FIG. 11 a schematic cross-sectional side view of an embodiment of microelectronic test interface substrate system FIG. 10 along line 7-7.

FIG. 12 is a schematic top view of an embodiment with 220 open trace conductor deposition and removal of resist or mask 920.

FIG. 13 a schematic cross-sectional side view of an embodiment of microelectronic test interface substrate system FIG. 12 along line 8-8.

FIG. 14 is a schematic top view of an embodiment with removal thin conductive seed layer deposition 910.

FIG. 15 a schematic cross-sectional side view of an embodiment of microelectronic test interface substrate system FIG. 14 along line 9-9.

FIG. 16 is a schematic top view of an embodiment with thin conductive seed layer deposition 910. resist or mask 920 layer applied and developed 950 on the trace pair 230.

FIG. 17 a schematic cross-sectional side view of an embodiment of microelectronic test interface substrate system FIG. 16 along line 10-10.

FIG. 18 a schematic top view of an embodiment with 230 short conductor trace removal, removal of resist or mask 920 and removal thin conductive seed layer deposition 910.

FIG. 19 a schematic cross-sectional side view of an embodiment of microelectronic test interface substrate system FIG. 18 along line 11-11.

FIG. 20 is a schematic top view of an embodiment with thin conductive seed layer deposition 910. resist or mask 920 layer applied and developed 950 on the trace pair 240.

FIG. 21 a schematic cross-sectional side view of an embodiment of microelectronic test interface substrate system FIG. 20 along line 12-12.

FIG. 22 a schematic top view of an embodiment with 240 conductor trace deposition and reshape, removal of resist or mask 920 and removal thin conductive seed layer deposition 910.

FIG. 23 a schematic cross-sectional side view of an embodiment of microelectronic test interface substrate system FIG. 22 along line 13-13.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The conductor repair process showing embodiments of the system are shown one repair at a time to demonstrate different types of major defects in the test interface redistribution layer system. However, multiple defects can be repaired at the same process and time.

The designation and usage of the term first, second, third, etc. is for convenience and clarity and is not meant limit a particular order. The steps or processes described can be performed in any order to implement the claimed subject matter.

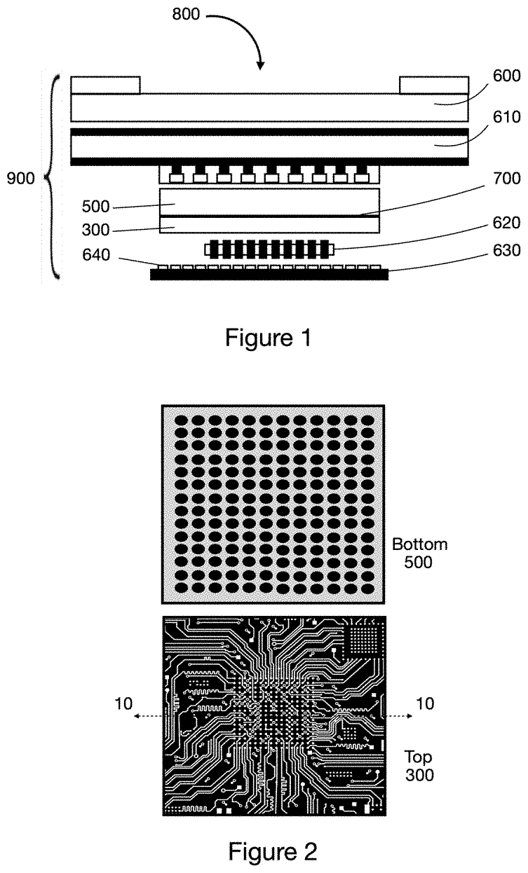

Referring now to FIG. 1, therein is shown a schematic side view of a probe card system 800 in an embodiment of the present invention 700 is integrated. The system 800 is a system for providing interconnection between different devices. For example, the system 800 can be a component in a wafer testing system 900 or a substrate in an integrated circuit packaging system. As an example, the wafer testing system 900 can include a mechanical stiffener 600, a printed circuit board 610, a redistribution test interface platform 700 consist of the base carrier substrate 500 and redistribution substrate platform 300, and a probe head 620. The mechanical stiffener 600, the printed circuit board 610, the redistribution test interface platform 700, and the probe head 620 are components for a system to test a semiconductor wafer 630. The semiconductor wafer 630 can include a die 640 with electronic components, such as circuits, integrated circuits, logic, integrated logic, or a combination thereof fabricated thereon.

Referring now to FIG. 2, therein is shown an embodiment of microelectronic test interface substrate system 300 of FIG. 1 and bottom view of base carrier substrate 500 of FIG. 1 of the redistribution test interface substrate platform 700. The bottom conductor pads of the test interface substrate are interconnecting toward the printed circuit board 610 of FIG. 1. The top side of the test interface substrates are interconnecting to the probe head 620 of FIG. 1. For wafer chip 630 of FIG. 1 and other logic and integrated devices to be tested.

The redistribution platform 700 is a structure for providing interconnection between two devices. For example, the redistribution platform 700 can be a space transformer, a redistribution structure for a multi-die package, or a combination thereof. The redistribution platform 700 can provide electrical and functional connectivity between semiconductor wafer 630, the die 640, or a combination thereof, and the rest of the redistribution system 800.

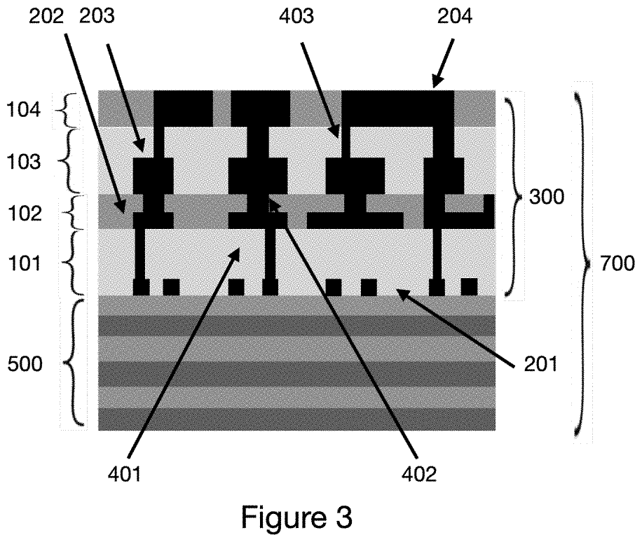

Referring now to FIG. 3, therein is shown an embodiment of microelectronic test interface substrate system cross-sectional side view of the test interface substrate manufacture by microelectronic redistribution system 700. The system 700 bottom conductor pads in FIG. 2 of the test interface substrate are interconnecting toward the printed circuit board 610 of FIG. 1. The top side of the test interface substrates pads in FIG. 2 are interconnecting to the probe head 620 of FIG. 1. For wafer chip 630 of FIG. 1 and other logic and integrated devices to be tested.

The platform 500 is a base carrier substrate providing interconnection between redistribution platform 300. For illustrative purposes, the redistribution platform 300 can provide electrical and functional connectivity between the semiconductor wafer, semiconductor dice, or a combination thereof for system testing, such as wafer testing, die testing, package testing, or inter-package testing.

The base carrier substrate 500 can be a rigid foundation or base layer for the redistribution player platform 300. The substrate 500 can include an electrically insulating material, such as a ceramic based or polymer composite based material.

For illustrate purpose, the microelectronic redistribution platform 300 consists only of 4 layers 101, 102, 103 and 104. The total test interface substrate redistribution layer counts can be more or less.

The microelectronics buildup redistribution system 300 layers can be signal layer, ground layer, power layer, plane layer or the combination thereof.

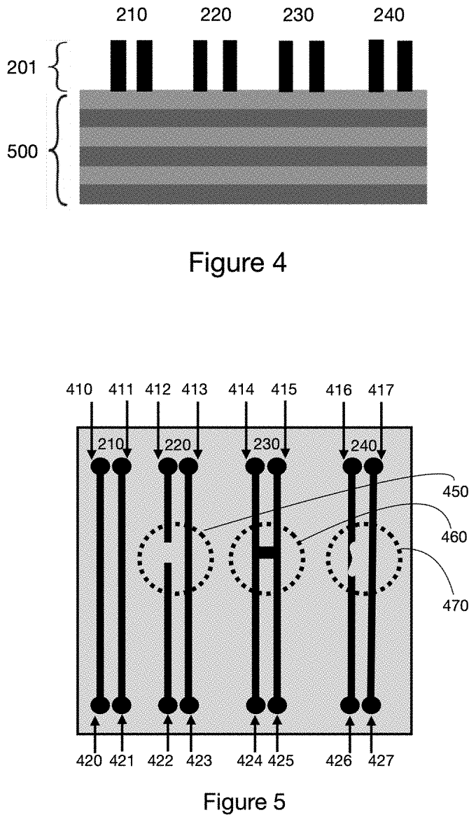

Referring now to FIG. 4, therein is an embodiment of microelectronic test interface substrate system shown cross-sectional side view of the test interface substrate 1^{st} redistribution conductor layer 201. For illustrative purpose, the redistribution conductor is depicted having a similar shape from the side view, although it is understood that the system 201 can have a different shape. For example, the redistribution conductor system 201 can have a shape to meet the needs of testing equipment or setup, such as a square, or rectangular shape, a triangular shape, pentagonal shape, or any other polygonal shapes and curves.

Referring now to FIG. 5, therein is an embodiment of microelectronic test interface substrate system shown top view of the test interface substrate in FIG. 4. For illustrative purpose, the distribution conductors are shown in pairs 210, 220, 230 and 240. System 210 is showing normal conductor connecting 410 to 420 and 411 to 421. System 220 is showing open circuit from 412 to 422 and normal circuit from 413 to 423. System 230 is showing short circuits between 4 conductor ends 414, 424, 415 and 425. System 240 is showing damaged conductor between 416 and 426, but normal conductor connecting 417 and 427. For normal conductor connections, the electrical test will pass and confirm the design validity. The open circuit between 412 and 422, short circuits of 414, 424, 415 and 425 will fail the electrical test. The damage circuit of 416 to 426 causes the leakage or improper signal propagation which also classified as defect circuit. Redistribution system 450 is open, system 460 is short and system 470 is leakage are the major test interface substrate defect causes.

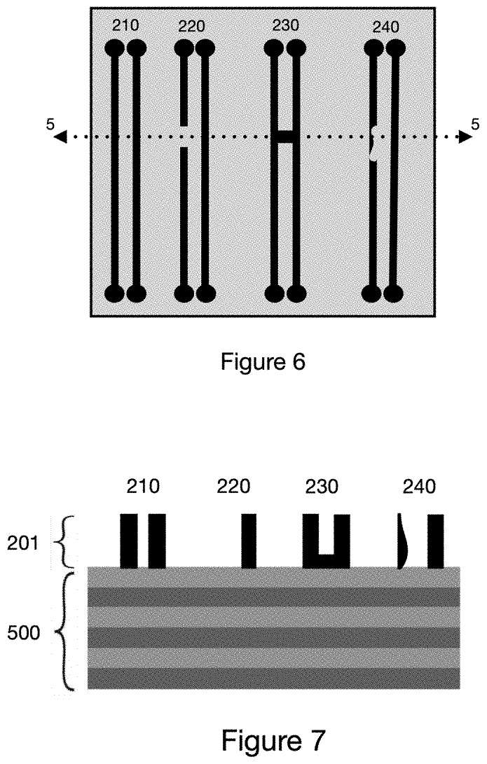

Referring now to FIG. 6, therein is an embodiment of microelectronic test interface substrate system top view with base carrier substrate and 1^{st} microelectronic redistribution buildup layer cross lined thru normal pairs, open pairs, short pairs, and damage pairs of conductor traces along the line 5-5.

FIG. 6 depicts the redistribution layer buildup of the 1^{st} layer. For example, the redistribution conductor system 201 FIG. 4 can have a shape of many forms and thickness such as a square, or rectangular shape and curves with high density design composition.

Referring now to FIG. 7 is an embodiment of microelectronic test interface substrate system schematic cross-sectional side view of FIG. 6 along line 5-5. System 210 showing normal side view with 2 parallel conductors. System 220 showing one conductor side view due to open conductor. System 230 shows conductor joining two parallel conductors side view due to short conductor. System 240 showing deform conductor side view.

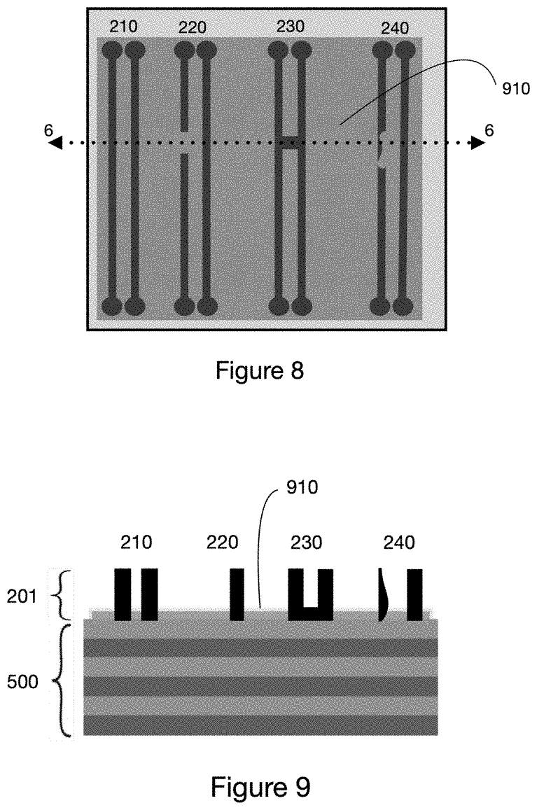

Referring now to FIG. 8, therein is an embodiment of microelectronic test interface substrate system shown top view with base carrier substrate and 1^{st} microelectronic buildup redistribution layer cross lined thru normal pairs, open pairs, short pairs, and damage pairs of conductor traces along line 6-6.

For illustrative purpose, thin seed layer of conductive deposition is made on the surface of the 1^{st} redistribution layer 910. The purpose of system 910 is for electrolytic conductor deposition for repair of damaged conductors. This thin conductive deposition seed layer is the same material as the conductors.

Referring now to FIG. 9 is an embodiment of microelectronic test interface substrate system schematic cross-sectional side view of FIG. 8 along line 6-6. System 210 showing normal side view with 2 parallel conductors. System 220 showing one conductor side view due to open conductor. System 230 shows conductor joining two parallel conductors side view due to short conductor. System 240 showing deform conductor side view. System 910 is thin conductive seed layer deposition.

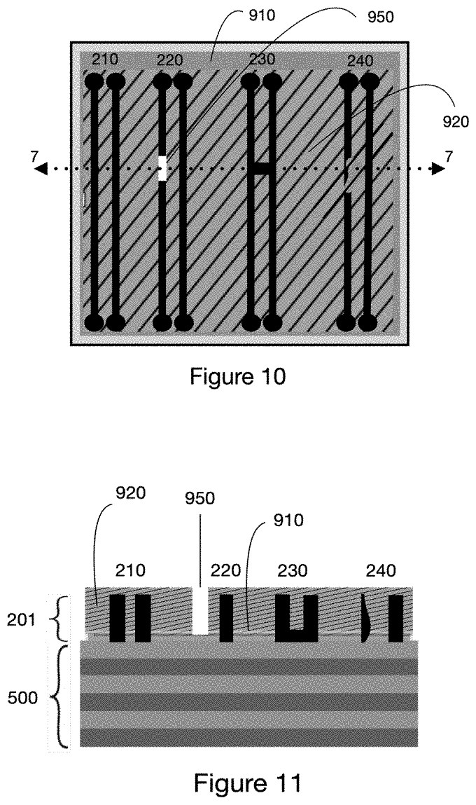

Referring now to FIG. 10, therein an embodiment of microelectronic test interface substrate system is shown top view with base carrier substrate and 1^{st} microelectronic buildup redistribution layer cross lined thru normal pairs, open pairs, short pairs, and damage pairs of conductor traces along line 7-7. For illustrative purpose, the layer of resist or mask 920 is applied to cover the redistribution layer conductor on top of FIG. 8. The open trace area of system 220 is selectively exposed and developed. System 950 is exposed and developed area which resist, or mask is removed.

Referring now to FIG. 11 is an embodiment of microelectronic test interface substrate system schematic cross-sectional side view of FIG. 10 along line 7-7. System 210 showing normal side view with 2 parallel conductors covered with resist or mask. System 220 showing opened resist or mask area 950 and one conductor covered with resist or mask. System 230 shows conductor joining two parallel conductors side view due to short conductor covered with resist or mask. System 240 showing deform conductor side view covered with resist or mask. System 910 is thin conductive seed layer deposition under resist or mask.

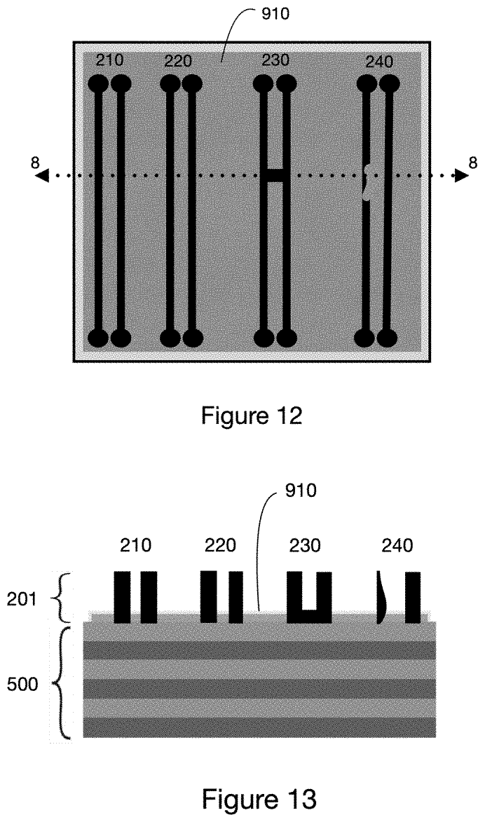

Referring now to FIG. 12 is an embodiment of microelectronic test interface substrate system schematic top view with 220 open trace conductor deposition and removal of resist or mask 920. The open conductor in system 220 is repaired by selective conductor electrolytic deposition done on open resist or mask area 950 in FIG. 10.

Referring now to FIG. 13 is an embodiment of microelectronic test interface substrate system schematic cross-sectional side view of FIG. 12 along line 8-8. System 210 showing normal side view with 2 parallel conductors. System 220 now also showing normal side view with 2 parallel conductors after repair is done. System 230 shows conductor joining two parallel conductors side view due to short conductor. System 240 showing deform conductor side view. System 910 is thin conductive seed layer deposition.

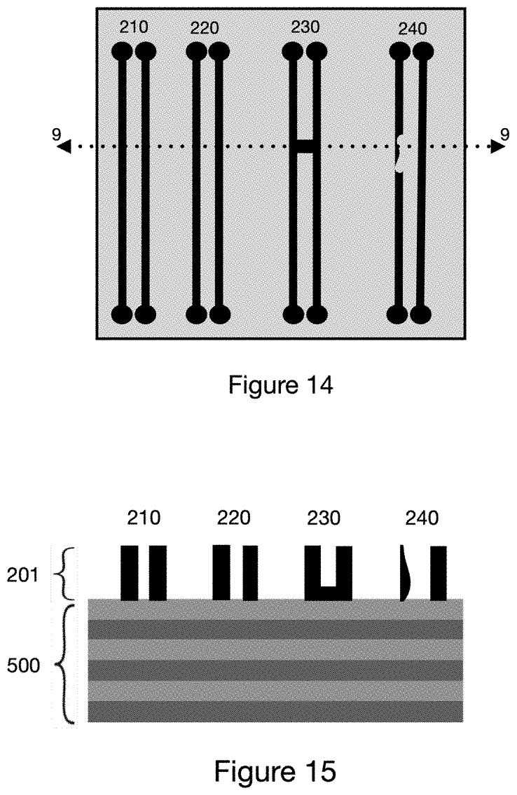

Referring now to FIG. 14 is an embodiment of microelectronic test interface substrate system schematic top view with removal of system 910 thin conductive seed layer deposition. The conductor in system 220 is fully repaired. For example, the test interface substrate can be electrically tested and validated for the functionality.

Referring now to FIG. 15 is an embodiment of microelectronic test interface substrate system schematic cross-sectional side view of FIG. 14 along line 9-9. System 210 showing normal side view with 2 parallel conductors. System 220 now also showing normal side view with 2 parallel conductors after repair is done. System 230 shows conductor joining two parallel conductors side view due to short conductor. System 240 showing deform conductor side view.

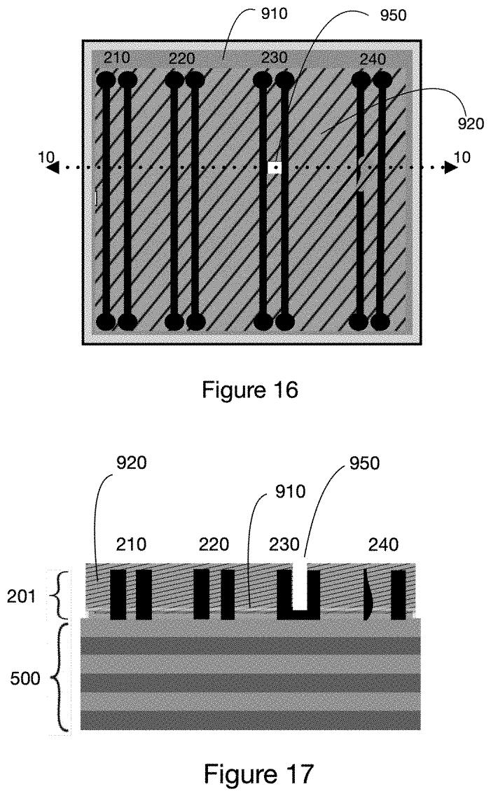

Referring now to FIG. 16, therein is an embodiment of microelectronic test interface substrate system shown top view of with base carrier substrate and 1^{st} microelectronic buildup redistribution layer cross lined thru normal pairs 210, normal pairs 220, short pairs 230 and damage pairs 240 of conductor traces along line 10-10. For illustrative purpose, the thin conductive seed layer 910 and the layer of resist or mask 920 is applied to cover the redistribution layer conductor on top of FIG. 14. The short trace area of system 230 is selectively exposed and developed. System 950 is exposed and developed area which resist, or mask is removed.

Referring now to FIG. 17 is an embodiment of microelectronic test interface substrate system schematic cross-sectional side view of FIG. 16 along line 10-10. System 210 showing normal side view with 2 parallel conductors covered with resist or mask. System 220 also showing normal side view with 2 parallel conductors covered with resist or mask. System 230 showing opened resist or mask area 950. System 240 showing deform conductor side view covered with resist or mask. System 910 is thin conductive seed layer deposition under resist or mask.

The distribution platform of FIG. 16 and FIG. 17 open resist or mask area is exposed and developed for conductor etching to remove short conductors.

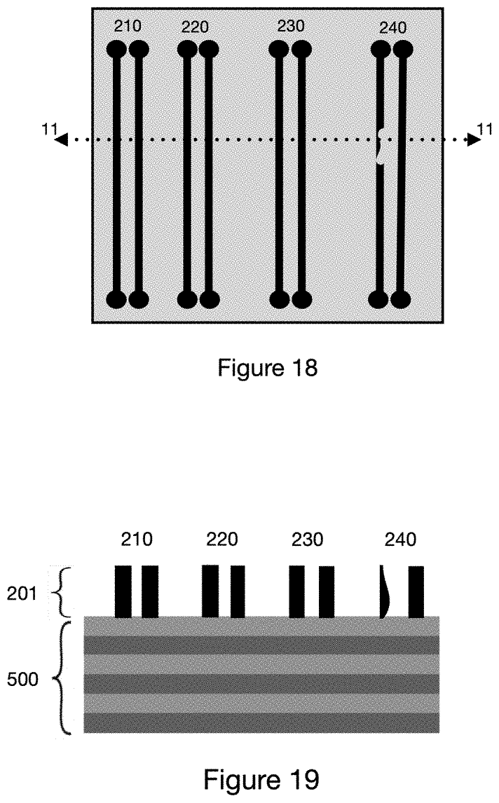

Referring now to FIG. 18 is an embodiment of microelectronic test interface substrate system schematic top view with removal of resist or mask system 920 and removal of system 910 thin conductive seed layer deposition. The conductor in system 230 is fully repaired. For example, the test interface substrate can be electrically tested and validated for the functionality.

Referring now to FIG. 19 is an embodiment of microelectronic test interface substrate system schematic cross-sectional side view of FIG. 18 along line 11-11. System 210 showing normal side view with 2 parallel conductors. System 220 showing normal side view with 2 parallel conductors after repair is done. System 230 now showing normal side view with 2 parallel conductors after repair is done. System 240 showing deform conductor side view.

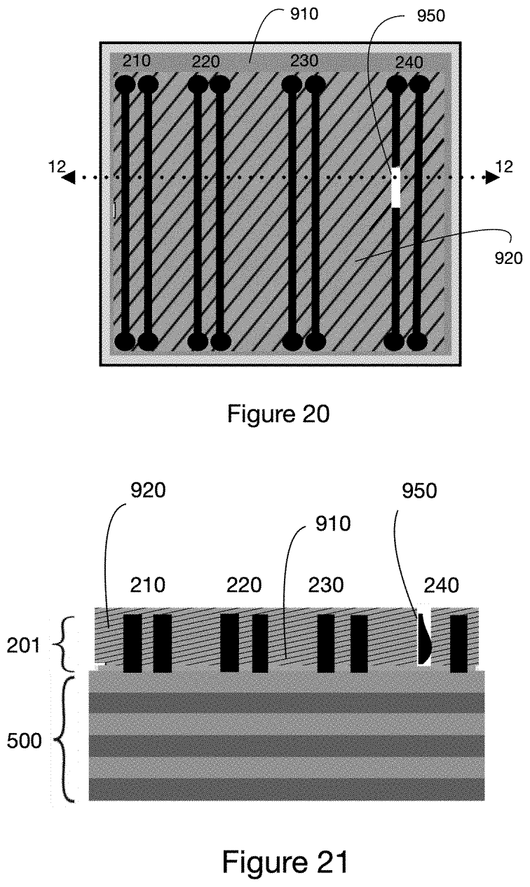

Referring now to FIG. 20, therein is shown an embodiment of microelectronic test interface substrate system top view with base carrier substrate and 1^{st} microelectronic buildup redistribution layer cross lined thru normal pairs 210, normal pairs 220, normal pairs 230 and damage pairs 240 of conductor traces along line 12-12. For illustrative purpose, the thin conductive seed layer 910 and the layer of resist or mask 920 is applied to cover the redistribution layer conductor on top of FIG. 18. The deformed trace area of system 240 is selectively exposed and developed. System 950 is exposed and developed area which resist, or mask is removed.

Referring now to FIG. 21 is an embodiment of microelectronic test interface substrate system schematic cross-sectional side view of FIG. 20 along line 12-12. System 210 showing normal side view with 2 parallel conductors covered with resist or mask. System 220 also showing normal side view with 2 parallel conductors covered with resist or mask. System 230 showing normal side view with 2 parallel conductors covered with resist or mask. System 240 showing deform conductor opened resist or mask area 950. System 910 is thin conductive seed layer deposition under resist or mask.

The distribution platform of FIG. 20 and FIG. 21 open resist or mask area is exposed and developed for conductor reshape and fix conductor by electrolytic conductor deposition.

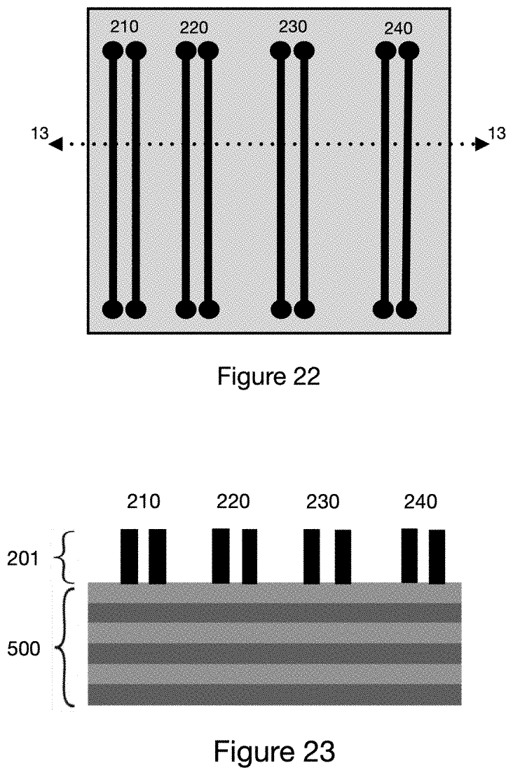

Referring now to FIG. 22 is an embodiment of microelectronic test interface substrate system schematic top view with removal of resist or mask system 920 and removal of system 910 thin conductive seed layer deposition. The conductor in system 240 is fully repaired. For example, the test interface substrate can be electrically tested and validated for the functionality.

Referring now to FIG. 22 is an embodiment of microelectronic test interface substrate system schematic cross-sectional side view of FIG. 22 along line 13-13. System 210, 220, 230 and 240 all showing normal side view with 2 parallel conductors.

Referring now to FIG. 23 is an embodiment of microelectronic test interface substrate system schematic top view after the complete repair of defective conductors. For example, the test interface substrate can be electrically tested and validated for the functionality.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of a foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. Microelectronic buildup redistribution layer system comprising: A, a substrate comprising base carrier, dielectric, conductor traces, conductor vias connecting layers. B, a microelectronic redistribution layers include a buildup process on base carrier. C, a microelectronic redistribution layers included the different or same layers.

2. Microelectronic buildup redistribution layer system of claim 1, wherein the via conductor provide an interlocking or connecting function with the top or bottom layer conductor.

3. Microelectronic buildup redistribution layer system of claim 1, wherein the base carrier substrate is a ceramic material in construction of single or multi-layers.

4. Microelectronic buildup redistribution layer system of claim 1, wherein the base carrier substrate is an organic, printed circuit board, material in construction of single or multi-layers.

5. Microelectronic buildup redistribution layer system of claim 1, wherein the base carrier substrate is a wafer.

6. Microelectronic buildup redistribution layer system of claim 1, wherein the base carrier substrate is a glass.

7. Microelectronic buildup redistribution layer system of claim 1, wherein the base carrier substrate is a quartz.

8. Microelectronic buildup redistribution layer system of claim 1, wherein the dielectric is a polyimide-based polymer material.

9. Microelectronic buildup redistribution layer system of claim 1, wherein the dielectric is an epoxy-based polymer material.

10. Microelectronic buildup redistribution layer system of claim 1, wherein the dielectric is a resin-based polymer material.

11. Microelectronic buildup redistribution layer system of claim 1, wherein the base carrier substrate includes a through substrate via in the substrate and connected to the conductor traces.

12. Microelectronic buildup redistribution layer system of claim 1, wherein the substrate is a polymer composite substrate.

13. A method of manufacturing microelectronic buildup redistribution layer system comprising and providing a substrate forming a plurality of microelectronic redistribution layers on the substrate, the redistributions layers including a dielectric layer and conductive (conductor) traces and forming a multi-layer structure by cross-linking or connecting layers by via conductor.

14. The method of claim 13, wherein forming the microelectronic redistribution layers includes the polymer layer as a polyimide-based polymer material.

15. The method of claim 13, wherein forming the redistribution layers includes the polymer layer as an epoxy-based polymer material.

16. The method of claim 13, wherein providing the substrate includes providing the substrate including a through substrate vias, and forming the redistribution layers include the conductive traces connected to the through substrate via.

17. The method of claim 13, wherein providing the substrate includes providing a ceramic substrate.

18. The method of claim 13, wherein providing the substrate includes providing a polymer composite substrate.

19. The method of claim 13, wherein providing the substrate includes providing many base materials.

20. The method of claim 13, wherein proving the substrate includes providing no lamination process for the multi-layered redistribution system.

21. The method of claim 13, wherein proving the substrate includes layer to layer buildup process for the multi-layered redistribution system.

22. The method of claim 13, wherein proving the substrate includes layer level repair and electrical test on buildup process for the multi-layered redistribution system.
